(19) United States
(12) Patent Application Publication
(10) Pub. No.: US 2007/0181948 A1
(43) Pub. Date: Aug. 9, 2007

(54) ESD protection device

(76) Inventors: Chorng-Wei Liaw, Zhubei City (TW); Ming-Jang Lin, Hsinchu City (TW); Wei-Jye Lin, Chaujou Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/498,235

(22) Filed: Aug. 3, 2006

(30) Foreign Application Priority Data
Feb. 7, 2006 (TW) 095104093

(51) Int. Cl. H01L 23/62

(52) U.S. Cl. 257/355

(57) ABSTRACT

The junction breakdown voltage of an ESD protection device is adjusted by altering the distance between two diffusion regions of opposite conductivity types.

### FIELD OF THE INVENTION

The present invention is related generally to a semiconductor device and, more particularly, to an electrostatic discharge (ESD) protection device.

### BACKGROUND OF THE INVENTION

The parasitic bipolar transistor in field metal-oxide-semiconductor (MOS) device or NMOS device is often used in the design of ESD protection. FIG. 1 shows a conventional ESD protection device 10, and FIG. 2 is an equivalent circuit 30 of the structure in FIG. 1. As shown, a P-type substrate 12 has a P-well 14, and a pair of P-type high concentration diffusion region 16 and N-type high concentration diffusion regions 18 and 20 are formed in the P-well 14. The high concentration diffusion regions 16, 18 and 20 are separated by a field oxide (FOX) 22. An insulator 24 covers the substrate 12, and contact windows 11, 13 and 15 are formed in the insulator 24 for the high concentration diffusion regions 16; 18 and 20, respectively. A conductive layer 26 is electrically connected to the high concentration diffusion regions 16 and 18 in the contact windows 11 and 13, so that the high concentration diffusion regions 16 and 18 are electrically connected to each other. A conductive layer 28 is electrically connected to the high concentration diffusion region 20 in the contact window 15. The P-well 14, the high concentration diffusion regions 18 and 20, the insulator 24, and the conductive layer 28 constitute a field MOS 32, a diode 38 is present between the high concentration diffusion region 20 and the P-well 14, the high concentration diffusion regions 18 and 20 and the P-well 14 constitute a lateral NPN (L-NPN) bipolar junction transistor (BJT) 34, and resistor 36 is referred to the substrate resistor. During operation, the conductive layers 26 and 28 are electrically connected to ground and a pad 31, respectively. When the pad 31 suffers an ESD event, the voltage on the pad 31 rises up rapidly, the rising voltage causes the diode 38 to break down, the breakdown current flows through the resistor 36 to pump the substrate voltage, and thereby the BJT 34 is turned on to release the ESD current from the pad 31. If the voltage on the pad 31 still increases continuously at this moment, the field MOS 32 will turn on to help releasing the ESD current. FIG. 3 shows a current-voltage curve 40 of the device shown in FIG. 1 during operation, FIG. 4 shows a current flowing diagram when it is at point A of the current-voltage curve 40, and FIG. 5 shows a current flowing diagram when it is at point B of the current-voltage curve 40. Referring to FIGS. 2 to 5, when an ESD event occurs, the junction between the high concentration diffusion region 20 and the P-well 14 suffers a reverse bias. As the reverse voltage increasing, the junction between the high concentration diffusion region 20 and the P-well 14 breaks down from a corner point 19. Under this circumstance, the current increases along the current-voltage curve 40, a large current crosses over the high concentration diffusion region 18 into the high concentration diffusion region 16, as shown in FIG. 4, and thereby the substrate voltage is pulled high to turn on the BJT 34. It causes the voltage dropping down along the current-voltage curve 40 and held on a holding voltage, and a large current from the high concentration diffusion region 20 flows into the high concentration diffusion region 18 so as to release the ESD current, as shown in FIG. 5.

FIG. 6 shows a conventional ESD protection device 42 for a low voltage NMOS (LV-NMOS) device, and FIG. 7 is an equivalent circuit 52 of the structure in FIG. 6. As shown, a P-type substrate 12 has a P-well 14, and a pair of P-type high concentration diffusion region 16 and N-type high concentration diffusion regions 18 and 20 are formed in the P-well 14. The high concentration diffusion region 16 and the high concentration diffusion regions 18 and 20 are separated by a field oxide (FOX) 45, and a gate 44 comprising a polysilicon layer 48 is spaced with a gate oxide 50 from a channel between the high concentration diffusion regions 18 and 20. An insulator 24 covers the gate 44, and contact windows 11, 13 and 15 are formed in the insulator 24 for the high concentration diffusion regions 16, 18 and 20, respectively. A conductive layer 26 is electrically connected to the high concentration diffusion regions 16 and 18 in the contact windows 11 and 13, so that the high concentration diffusion regions 16 and 18 are electrically connected to each other. A conductive layer 46 is electrically connected to the high concentration diffusion region 20 in the contact window 15. The gate 44 and the high concentration diffusion regions 18 and 20 constitute a NMOS 54. A diode 38 is present between the high concentration diffusion region 20 and the P-well 14, the high concentration diffusion regions 18 and 20 and the P-well 14 constitute a L-NPN BJT 34, and resistor 36 is referred to the substrate resistor. During operation, the conductive layers 26 and 46 are electrically connected to ground and a pad 31, respectively. When the pad 31 suffers an ESD event, along with the rising voltage, the diode 38 breaks down, the breakdown current flows through the resistor 36 to pump the substrate voltage, and thereby the BJT 34 is turned on to release the ESD current from the pad 31.

FIG. 8 shows a conventional ESD protection device 56 for a BJT process application, and FIG. 9 is a circuit diagram 100 of the structure in FIG. 8. As shown, N-type buried diffusion layers 76 and 86 are formed on a P-type substrate 60, and a N-type epitaxial layer 62 is formed on the substrate 60 and covers the buried diffusion layers 76 and 86. P-type diffusion regions 70, 72 and 80 and N-type diffusion regions 74 and 84 are formed in the epitaxial layer 62, and N-type diffusion regions 82 and 58 are formed in the P-type diffusion region 80 and the N-type diffusion region 84, respectively. The P-type diffusion regions 70 and 72 and the N-type diffusion region 74 constitute a lateral PNP (L-PNP) BJT 102, and the N-type diffusion regions 82 and 84 and the P-type diffusion region 80 constitute a vertical NPN (V-NPN) BJT 106. The BJTs 102 and 106 are separated by P-type isolation diffusion regions 64, 68 and 78. A conductive layer 90 is formed on the isolation diffusion regions 64 and 78, the P-type diffusion regions 70, 72 and 80, and the N-type diffusion regions 74, 82 and 58. An insulator 88 is formed on the epitaxial layer 62 and covers a portion of the conductive layer 90. The N-type diffusion regions 74 and 84 constitute the collectors of the BJT 102 and 106, the N-type epitaxial layer 62 is used to increase the endurable voltage of the device, and the doped concentration of the N-type diffusion region 58 is higher than that of the N-type diffusion region 84 to act as a contact area. In this case, the BJT 106 acts as an ESD protection device. FIG. 10 is an equivalent circuit of the structure in FIG. 9, and FIG. 11 shows a structure 114 of the BJT 106. As shown, a conductive layer 116 is formed on the N-type diffusion region 82 and electrically contacts the N-type diffusion region 82 to act as the emitter (E) of the BJT 106, a conductive layer 118 is formed on the P-type diffusion region 80 and electrically contacts the P-type diffusion region 80 to act as the base (B) of the BJT 106, and a conductive layer 120 is formed on the N-type diffusion region 58 and electrically contacts the N-type diffusion region 58 to act as the collector (C) of the BJT 106. The junction between the P-type diffusion region 80 and the N-type epitaxial layer 62 constitute a diode 112, and resistor 110 is referred to the substrate resistor. When the pad 104 suffers an ESD event, along with the rising voltage, the diode 112 breaks down, the breakdown current flows through the resistor 110 to pump the substrate voltage, and thereby the BJT 106 is turned on to release the ESD current from the pad 104.

The above-mentioned arts show that the conventional ESD protection devices achieve the goal of ESD protection by producing an increasing current resulted from the PN junction breakdown to trigger the BJT to turn on. However, the breakdown voltage of a PN junction depends on the dopant concentration of the PN junction. In a semiconductor process, the PN junction breakdown voltage of an ESD protection device and that of the core circuit of the integrated circuit (IC) have no great difference, and thereby the ESD protection device can not protect the core circuit of the IC from damages effectively. Though there are already several improved methods to reduce the breakdown voltage of an ESD protection device, however, they are attained by changing the dopant concentration of the PN junction, and therefore it is often needed to increase the process steps and the process complexity accordingly. For example, U.S. Pat. No. 5,559,352 to Hsue et al. discloses an ESD protection device improvement, which adds a step of lightly ion implantation to reduce the junction breakdown voltage. Furthermore, the holding voltage of an ESD protection device is required higher than the power source voltage VCC, in order to protect the core circuit of an IC from ESD damages. However, conventionally, due to the power source voltage VCC (for example 24V) of a high voltage CMOS (HV-CMOS) device always higher than the holding voltage (for example 13V), the HV-NMOS device or the HV-PMOS device can not operate in the breakdown region. When an ESD event occurs, the ESD protection device is not only unable to protect the HV-CMOS device but also causes the power of the HV-CMOS device short to ground, resulting in damages to the circuit.

Therefore, it is desired an ESD protection device without increasing the process steps and capable of applying to HV-CMOS device.

### SUMMARY OF THE INVENTION

An object of the present invention is to provide an ESD protection device without increasing the process steps and capable of applying to HV-CMOS device.

According to the present invention, an ESD protection device comprises a substrate of a first conductivity type having a well of the first conductivity type, a first high concentration diffusion region of the first conductivity type, a second high concentration diffusion region of a second conductivity type opposite to the first conductivity type, a third high concentration diffusion region of the second conductivity type, and a fourth high concentration diffusion region of the first conductivity type all in the well, a first conductive layer electrically connecting to the first and second high concentration diffusion regions, and a second conductive layer electrically connecting to the third high concentration diffusion region. By altering the distance between the third and fourth high concentration diffusion regions, the breakdown voltage of the ESD protection device is adjusted.

According to the present invention, an ESD protection device comprises a substrate of a first conductivity type having a well of the first conductivity type, a first high concentration diffusion region of the first conductivity type, a second high concentration diffusion region of a second conductivity type opposite to the first conductivity type, a third high concentration diffusion region of the second conductivity type, and a fourth high concentration diffusion region of the first conductivity type all in the well, a gate above a channel between the second and third high concentration regions, a first conductive layer electrically connecting to the first and second high concentration diffusion regions, and a second conductive layer electrically connecting to the third high concentration diffusion region. By altering the distance between the third and fourth high concentration diffusion regions, the breakdown voltage of the ESD protection device is adjusted.

According to the present invention, an ESD protection device comprises a substrate of a first conductivity type, an epitaxial layer of a second conductivity type opposite to the first conductivity type on the substrate, a first diffusion region of the first conductivity type and a second diffusion region of the second conductivity type in the epitaxial layer, a third diffusion region of the second conductivity type in the first diffusion region, and a fourth diffusion region of the second conductivity type extending from the second diffusion region to a portion of the epitaxial layer between the first and second diffusion regions. By altering the distance between the first and fourth diffusion regions, the breakdown voltage of the ESD protection device is adjusted.

According to the present invention, an ESD protection device comprises a substrate of a first conductivity type having a first well of the first conductivity type and a second well of a second conductivity type opposite to the first conductivity type adjacent to each other, a first high concentration diffusion region of the first conductivity type in the first well, and a second high concentration diffusion region of the second conductivity type in the second well. By altering the distance between the first and second high concentration diffusion regions, the breakdown voltage of the ESD protection device is adjusted.

In a structure of the present invention, it is the distance between two diffusion regions of opposite conductivity types used to reduce the junction breakdown voltage of the ESD protection device. Without increasing the process steps, it solves the problems of the conventional techniques and is capable of utilizing in HV-CMOS device.

### BRIEF DESCRIPTION OF DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a conventional ESD protection device;

FIG. 2 shows an equivalent circuit of the structure in FIG. 1;

FIG. 3 shows a current-voltage curve of the device of FIG. 1 during operation;

FIG. 4 shows a current flowing diagram when it is at point A of the current-voltage curve of FIG. 3;

FIG. 5 shows a current flowing diagram when it is at point B of the current-voltage curve of FIG. 3;

FIG. 6 shows a conventional ESD protection device for a LV-NMOS device;

FIG. 7 shows an equivalent circuit of the structure in FIG. 6;

FIG. 8 shows a conventional ESD protection device for a BJT process application;

FIG. 9 shows a circuit diagram of the structure in FIG. 8;

FIG. 10 shows an equivalent circuit of the structure in FIG. 9;

FIG. 11 shows a BJT structure for the ESD protection in FIG. 8;

FIG. 12 shows an ESD protection device according to the present invention;

FIG. 13 shows an equivalent circuit of the structure in FIG. 12;

FIG. 14 shows a current-voltage curve of the device of FIG. 12 during operation;

FIG. 15 shows a current flowing diagram when it is at point A of the current-voltage curve of FIG. 14;

FIG. 16 shows a current flowing diagram when it is at point B of the current-voltage curve of FIG. 14;

FIG. 17 shows a comparison between the conventional current-voltage curve and the current-voltage curve of the present invention;

FIG. 18 shows an ESD protection device for a LV-NMOS device according to the present invention;

FIG. 19 shows an equivalent circuit of the structure in FIG. 18;

FIG. 20 shows an ESD protection device for a the BJT process application according to the present invention;

FIG. 21 shows an equivalent circuit of the structure in FIG. 20;

FIG. 22 shows an ESD protection device for a HV-CMOS device according to the present invention;

FIG. 23 shows a relationship of the distance between the high concentration diffusion region and the well and the breakdown voltage in FIG. 22; and

FIG. 24 shows a relationship of the distance between the high concentration diffusion region and the well and the breakdown voltage in FIG. 22.

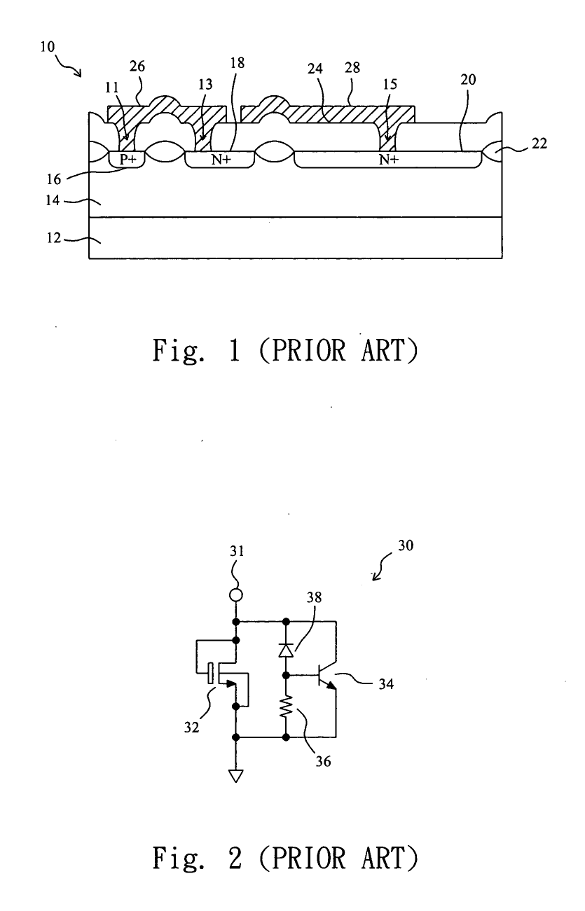

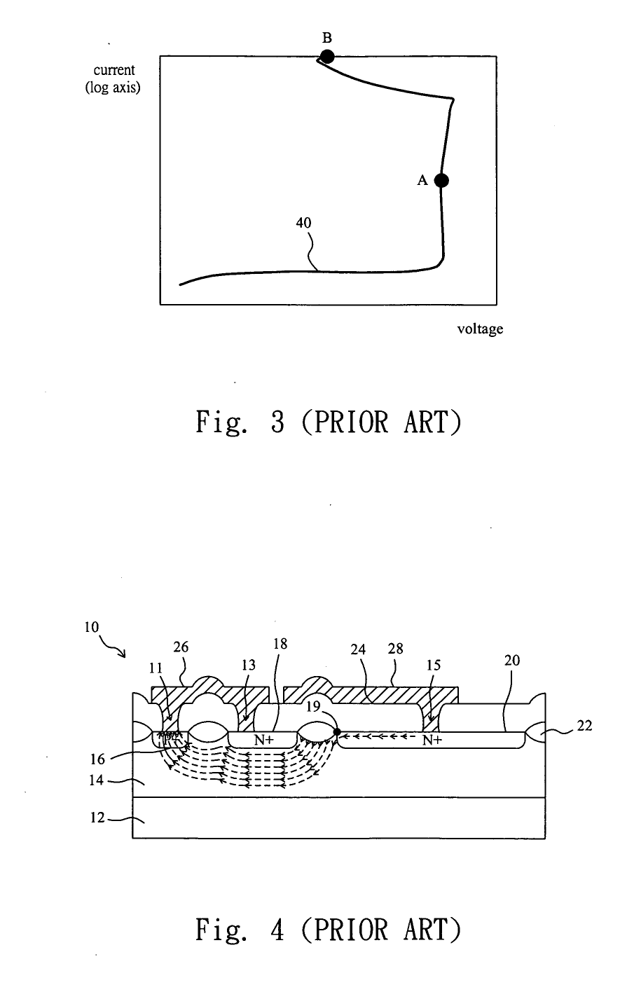

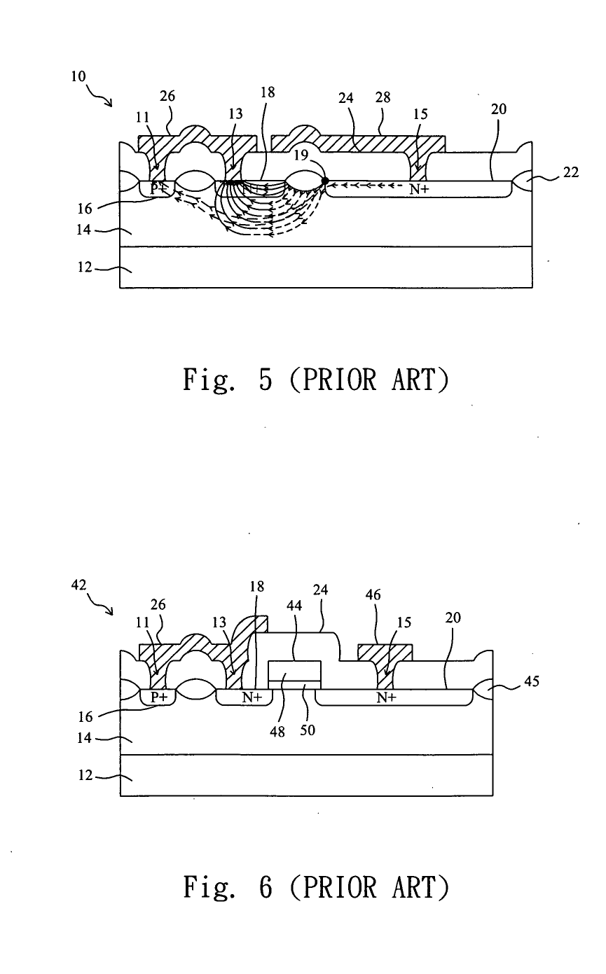

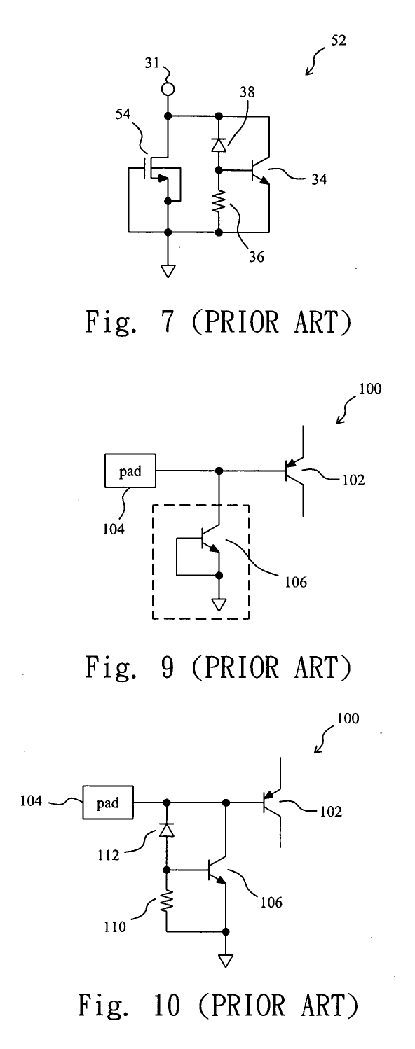

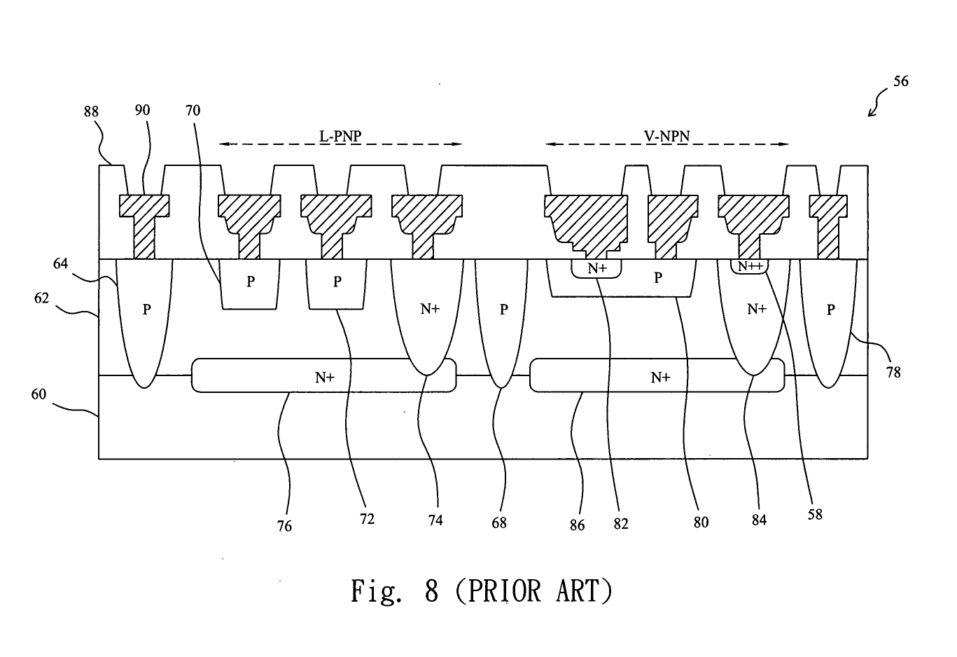

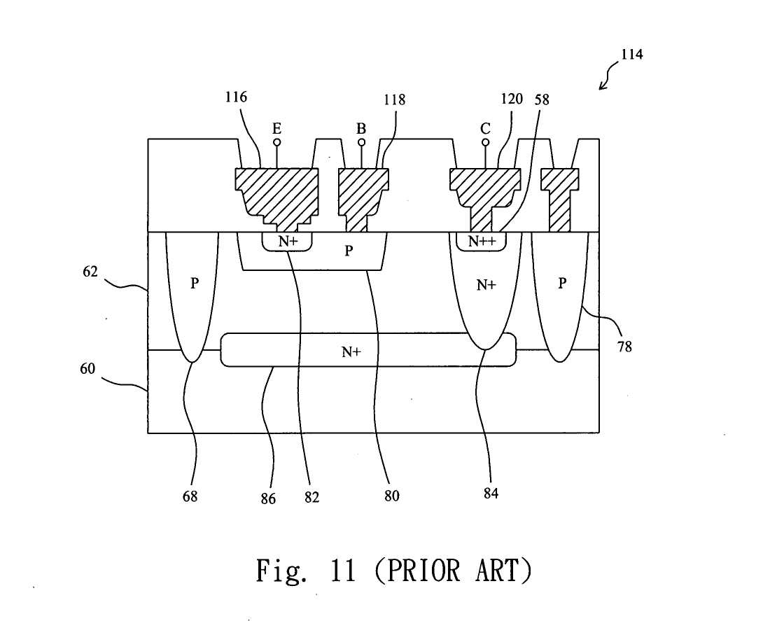

### DETAILED DESCRIPTION OF THE INVENTION

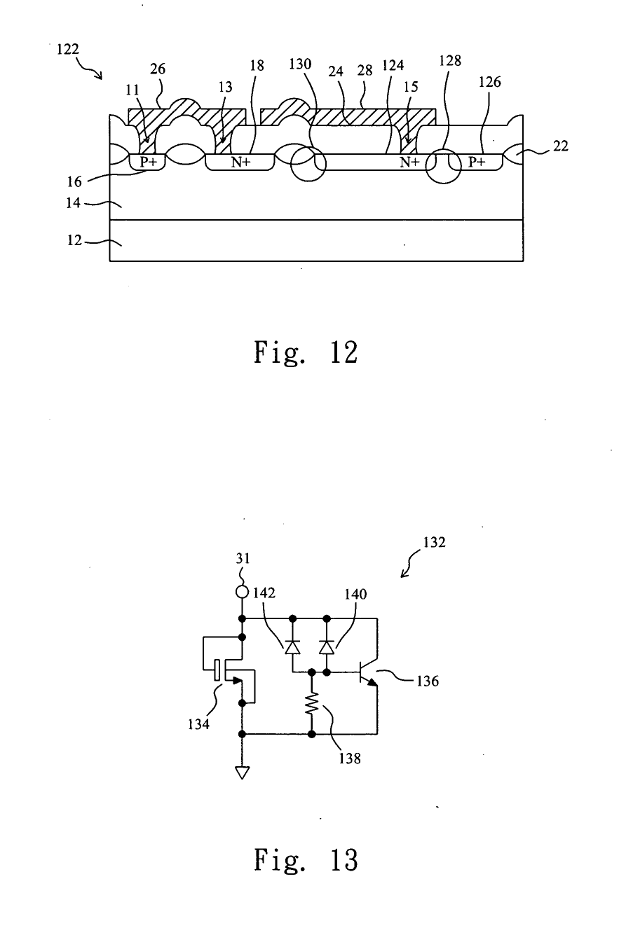

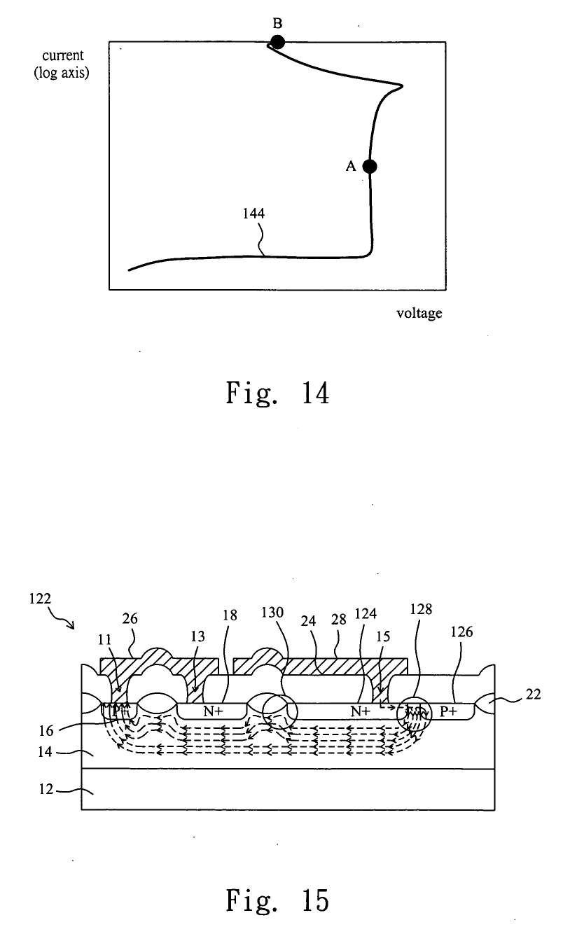

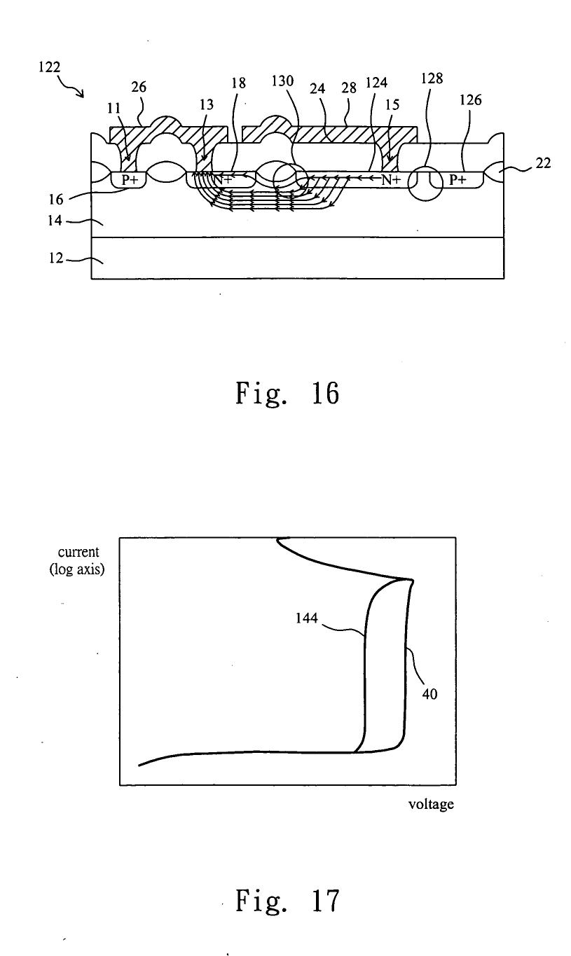

FIG. 12 shows an ESD protection device 122 according to the present invention, and FIG. 13 shows an equivalent circuit thereof. As shown, a substrate 12, for example of P-type conductivity, has a well 14 of the same conductivity type as that of the substrate 12. High concentration diffusion regions 16 and 126 of the same conductivity type as that of the substrate 12 and high concentration diffusion regions 18 and 124 of the opposite conductivity type (for example N-type) are formed in the well 14, and the high concentration diffusion regions 126 and 124 are separated by a distance D. The high concentration diffusion regions 16 and 18 and the high concentration diffusion regions 124 and 126 are separated by a field oxide (FOX) 22. An insulator 24 covers the substrate 12, and contact windows 11, 13 and 15 are formed in the insulator 24 for the high concentration diffusion regions 16, 18 and 124, respectively. A conductive layer 26, for example of metal, is electrically connected to the high concentration diffusion regions 16 and 18 in the contact windows 11 and 13, so that the high concentration diffusion regions 16 and 18 are electrically connected to each other. A conductive layer 28, for example of metal, is electrically connected to the high concentration diffusion region 124 in the contact window 15. The well 14, high concentration diffusion regions 18 and 124, insulator 24, and conductive layer 28 constitute a field MOS 134. The junction in a region 130 constitutes a diode 140, and the junction in a region 128 constitutes another diode 142. The high concentration diffusion regions 18 and 124 and the well 14 constitute a L-NPN BJT 136, and resistor 138 is referred to the substrate resistor. During operation, the conductive layers 26 and 28 are electrically connected to ground and a pad 31, respectively. When the pad 31 suffers an ESD event, the voltage on the pad 31 rises up rapidly. Along with the rising voltage, the diode 142 breaks down first since its breakdown voltage is lower than that of the diode 140. The breakdown current flows through the resistor 138 to pump the substrate voltage, and thereby the BJT 136 is turned on to release the ESD current from the pad 31. FIG. 14 shows a current-voltage curve 144 of the device 122 during operation, FIG. 15 shows a current flowing diagram when it is at point A of the current-voltage curve 144, and FIG. 16 shows a current flowing diagram when it is at point B of the current-voltage curve 144. Referring to FIGS. 13 to 16, when an ESD event occurs, the regions 128 and 130 are reverse biased. Along with the rising voltage, the breakdown starts from the region 128 since the breakdown voltage of the region 128 is lower than that of the region 130. Under this circumstance, the current increases rapidly along the current-voltage curve 144, a large current from the region 128 crosses over the high concentration diffusion regions 124 and 18 into the high concentration diffusion region 16, as shown in FIG. 15, and thereby the substrate voltage is pulled high to turn on the BJT 136. It causes the voltage dropping down along the current-voltage curve 144 and held on a holding voltage. A large current from the high concentration diffusion region 124 flows into the high concentration diffusion region 18 to release the ESD current, as shown in FIG. 16. FIG. 17 shows a comparison of the conventional current-voltage curve 44 and the current-voltage curve 144 of the present invention, which shows the breakdown voltage of the present invention lower than the conventional one. In this embodiment, the high concentration diffusion regions 126 and 16 are formed in a same step and no process steps are added. Furthermore, the breakdown voltage of the diode 142 is determined by the distance D. By adjusting the distance D, the breakdown voltage of the diode 142 is lower than those of the diode 140 and the PN junctions of the core circuit of the IC. When an ESD occurs, the diode 142 breaks down earlier than the diode 140 and the core circuit of the IC to trigger the ESD protection device 122 to protect the core circuit of the IC from damages effectively.

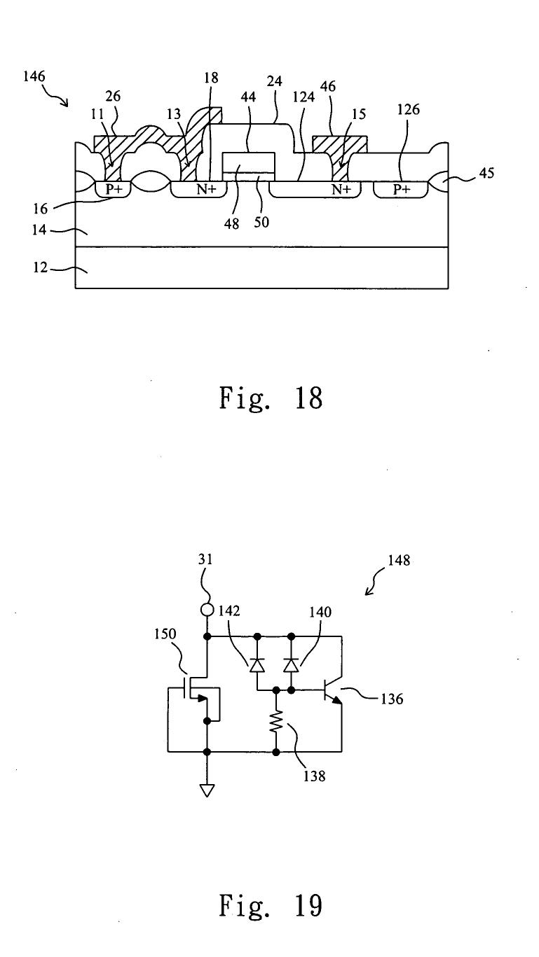

FIG. 18 shows an ESD protection device 146 for a LV-NMOS device, and FIG. 19 is an equivalent circuit 148 thereof. As shown, a substrate 12, for example of P-type conductivity, has a well 14 of the same conductivity type as that of the substrate 12. High concentration diffusion regions 16 and 126 of the same conductivity type as that of the substrate 12 and high concentration diffusion regions 18 and 124 of the opposite conductivity type (for example N-type) are formed in the well 14, and the high concentration diffusion regions 126 and 124 are separated by a distance D. The high concentration diffusion region 16 and the high concentration diffusion regions 18, 124 and 126 are separated by a field oxide (FOX) 45. A gate 44 comprising a polysilicon layer 48 is spaced with a gate oxide 50 from a channel between the high concentration diffusion regions 18 and 124. An insulator 24 covers the gate 44, and contact windows 11, 13 and 15 are formed in the insulator 24 for the high concentration diffusion regions 16, 18 and 124, respectively. A conductive layer 26 is electrically connected to the high concentration diffusion regions 16 and 18 in the contact windows 11 and 13, so that the high concentration diffusion regions 16 and 18 are electrically connected to each other. A conductive layer 46 is electrically connected to the high concentration diffusion region 124 in the contact window 15. The gate 44 and the high concentration diffusion regions 18 and 124 constitute a NMOS 150. A diode 140 is present between the high concentration diffusion region 124 and the well 14, and a diode 142 is present between the high concentration regions 124 and 126. The high concentration diffusion regions 18 and 124 and the well 14 constitute a L-NPN BJT 136, and resistor 138 is referred to the substrate resistor. During operation, the conductive layers 26 and 46 are electrically connected to ground and a pad 31, respectively. When the pad 31 suffers an ESD event, along with the rising voltage, the diode 142 breaks down first since its breakdown voltage is lower than that of the diode 140. The breakdown current flows through the resistor 138 to pump the substrate voltage, and thereby the BJT 136 is turned on to release the ESD current from the pad 31. Similarly, in this embodiment, by altering the distance D, the breakdown voltage of the ESD protection device 146 is adjusted so as to protect the core circuit of the IC from damages effectively.

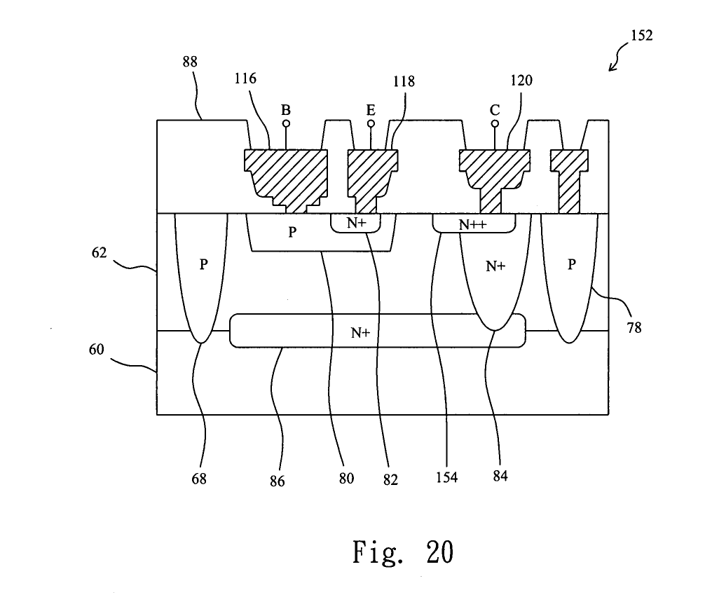

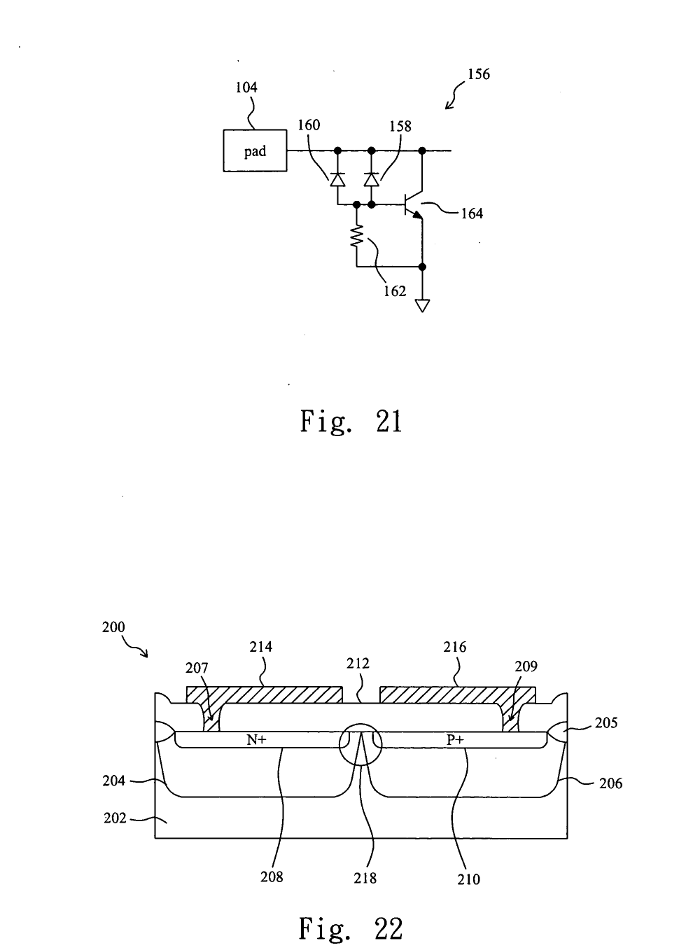

FIG. 20 shows an ESD protection device 152 for a BJT process application, and FIG. 21 is an equivalent circuit 156 thereof. As shown, a substrate 60, for example of P-type conductivity, has a buried diffusion layer 86 of the opposite conductivity type (for example N-type). An epitaxial layer 62 of the conductivity type opposite to that of the substrate 60 covers the buried diffusion layer 86. A diffusion region 80 of the same conductivity type as that of the substrate 60 and a diffusion region 84 of the conductivity type opposite to that of the substrate 60 are formed in the epitaxial layer 62, and a diffusion region 82 of the conductivity type opposite to that of the substrate 60 is formed in the diffusion region 80. A diffusion region 154 of the conductivity type opposite to that of the substrate 60 extends from the diffusion region 84 to a portion of the epitaxial layer 62 between the diffusion regions 80 and 84. The above-mentioned structures are isolated into an independent unit by isolation diffusion regions 68 and 78 of the same conductivity type as that of the substrate 60. A conductive layer 116 is electrically connected to the diffusion region 80, a conductive layer 118 is electrically connected to the diffusion region 82, and a conductive layer 120 is electrically connected to the diffusion region 154. An insulator 88 covers a portion of each of the conductive layers 116, 118 and 120. The diffusion regions 82 and 80 and the epitaxial layer 62 constitute a V-NPN BJT 164, a diode 158 is present between the diffusion region 80 and the epitaxial layer 62, a diode 160 is present between the diffusion regions 80 and 154, and resistor 162 is referred to the substrate resistor. The diffusion region 84 is the collector of the BJT 164, the diffusion region 80 is the base, the diffusion region 82 is the emitter, the epitaxial layer 62 is used to increase the endurable voltage of the BJT 164, and the doped concentration of the diffusion region 154 is higher than that of the diffusion region 84 to act as a contact area. In this embodiment, the conductive layer 116 is the base (B) of the BJT 164, the conductive layer 118 is the emitter (E) of the BJT 164, and the conductive layer 120 is the collector (C) of the BJT 164. Similarly, when the pad 104 suffers an ESD event, along with the rising voltage, the diode 160 breaks down first since its breakdown voltage is lower than that of the diode 158. The breakdown current flows through the resistor 160 to pump the substrate voltage, and thereby the BJT 164 is turned on to release the ESD current from the pad 31. Similarly, in this embodiment, by altering the distance between the diffusion regions 80 and 154, the breakdown voltage of the ESD protection device 152 is adjusted so as to protect the core circuit of the IC from damages effectively.

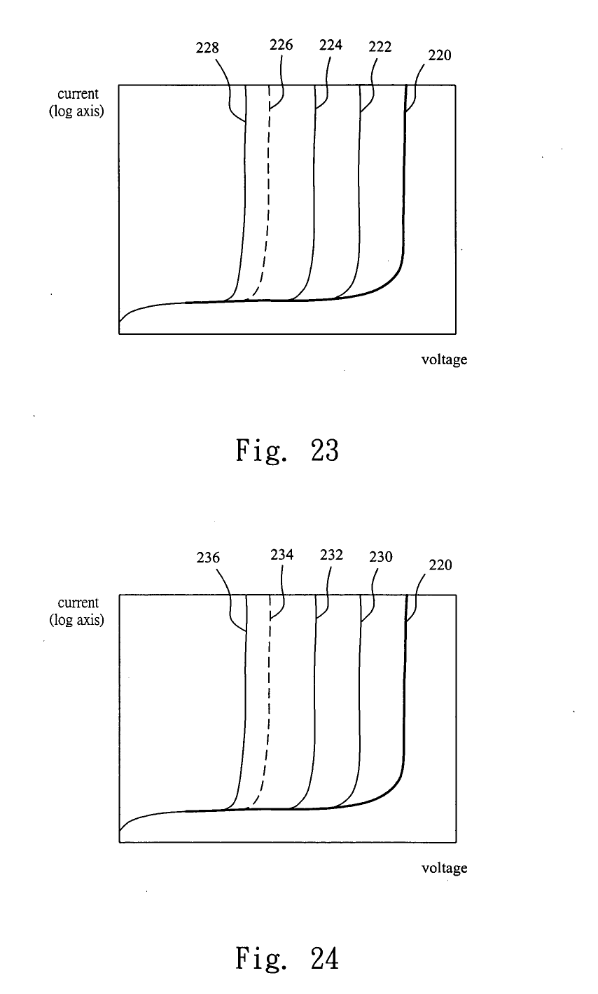

FIG. 22 shows an ESD protection device 200 for a HV-CMOS device. A substrate 202, for example of P-type conductivity, has a well 204 of the conductivity type opposite to that of the substrate 202 and a well 206 of the same conductivity type as that of the substrate 202. A high concentration diffusion region 208 of the conductivity type opposite to that of the substrate 202 is formed in the well 204, and a high concentration diffusion region 210 of the same conductivity type as that of the substrate 202 is formed in the well 206. An insulator 212 covers the substrate 202, and contact windows 207 and 209 are formed in the insulator 212 for the high concentration diffusion regions 208 and 210, respectively. Conductive layers 214 and 216 are electrically connected to the high concentration diffusion regions 208 and 210 in the contact windows 207 and 209, respectively. The above-mentioned structures are isolated into an independent unit by a field oxide 205. The region 218 forms a clamping diode. By adjusting the distance between the high concentration diffusion region 208 and the well 206 and the distance between the high concentration diffusion region 210 and the well 204 to adjust the distance between the high concentration diffusion regions 208 and 210, the breakdown voltage of the clamping diode is between the power source voltage VCC and the breakdown voltage of the HV-CMOS device. When an ESD event occurs, due to the breakdown voltage of the clamping diode lower than that of the HV-CMOS device, the clamping diode breaks down earlier than the HV-CMOS device, and since the breakdown voltage of the clamping diode is higher than the power source voltage VCC, the power of the HV-CMOS device will not be short to ground. In other embodiments, by adjusting the distance between the high concentration diffusion region 208 and the well 206 or the distance between the high concentration diffusion region 210 and the well 204 to adjust the distance between the high concentration diffusion regions 208 and 210, the breakdown voltage of the clamping diode is between the power source voltage VCC and the breakdown voltage of the HV-CMOS device. FIG. 23 shows a relationship of the distance between the high concentration diffusion region 208 and the well 206 and the breakdown voltage. When the distance between the high concentration diffusion region 208 and the well 206 decreases gradually, the current-voltage curve shifts from 220, 222, 224, 226 to 228 gradually, and the breakdown voltage also decreases gradually. FIG. 24 shows a relationship of the distance between the high concentration diffusion region 210 and the well 204 and the breakdown voltage. When the distance between the high concentration diffusion region 210 and the well 204 decreases gradually, the current-voltage curve shifts from 220, 230, 232, 234 to 236 gradually, and the breakdown voltage also decreases gradually.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. An ESD protection device, comprising:
a substrate of a first conductivity type having a well of said first conductivity type;
a first high concentration diffusion region of said first conductivity type, a second high concentration diffusion region of a second conductivity type opposite to said first conductivity type, a third high concentration diffusion region of said second conductivity type, and a fourth high concentration diffusion region of said first conductivity type, all in said well;
a first conductive layer electrically connecting to said first and second high concentration diffusion regions; and
a second conductive layer electrically connecting to said third high concentration diffusion region;
wherein said third and fourth high concentration diffusion regions are spaced with therebetween a distance to adjust a breakdown voltage of said ESD protection device.

2. The ESD protection device of claim 1, wherein each of said first and second conductive layers comprises a metal layer.

3. The ESD protection device of claim 1, wherein said first conductive layer is electrically grounded.

4. The ESD protection device of claim 1, wherein said second conductive layer is electrically connected to a pad.

5. An ESD protection device, comprising:
a substrate of a first conductivity type having a well of said first conductivity type;
a first high concentration diffusion region of said first conductivity type, a second high concentration diffusion region of a second conductivity type opposite to said first conductivity type, a third high concentration diffusion region of said second conductivity type, and a fourth high concentration diffusion region of said first conductivity type, all in said well;
a gate above a channel between said second and third high concentration regions;
a first conductive layer electrically connecting to said first and second high concentration diffusion regions; and
a second conductive layer electrically connecting to said third high concentration diffusion region;
wherein said third and fourth high concentration diffusion regions are spaced with therebetween a distance to adjust a breakdown voltage of said ESD protection device.

6. The ESD protection device of claim 5, wherein each of said first and second conductive layers comprises a metal layer.

7. The ESD protection device of claim 5, wherein said first conductive layer is electrically grounded.

8. The ESD protection device of claim 5, wherein said second conductive layer is electrically connected to a pad.

9. The ESD protection device of claim 5, wherein said gate comprises a polysilicon layer spaced from said channel with a gate oxide therebetween.

10. An ESD protection device, comprising:
a substrate of a first conductivity type;
an epitaxial layer of a second conductivity type opposite to said first conductivity type on said substrate;
a first diffusion region of said first conductivity type and a second diffusion region of said second conductivity type both in said epitaxial layer;
a third diffusion region of said second conductivity type in said first diffusion region; and
a fourth diffusion region of said second conductivity type extending from said second diffusion region to a portion of said epitaxial layer between said first and second diffusion regions;
wherein said first and fourth diffusion regions are spaced with therebetween a distance to adjust a breakdown voltage of said ESD protection device.

11. The ESD protection device of claim 10, wherein said second diffusion region constitutes a transistor collector.

12. The ESD protection device of claim 10, wherein said fourth diffusion region has a doped concentration higher than that of said second diffusion region.

13. The ESD protection device of claim 10, wherein said first diffusion region constitutes a transistor base.

14. The ESD protection device of claim 10, wherein said third diffusion region constitutes a transistor emitter.

15. An ESD protection device, comprising:
a substrate of a first conductivity type having a first well of said first conductivity type and a second well of a second conductivity type opposite to said first conductivity type, both adjacent to each other;
a first high concentration diffusion region of said first conductivity type in said first well; and
a second high concentration diffusion region of said second conductivity type in said second well;
wherein said first and second high concentration diffusion regions are spaced with therebetween a distance to adjust a breakdown voltage of said ESD protection device.
